(19) United States
(12) Patent Application Publication
(10) Pub. No.: US 2026/0172033 A1
(43) Pub. Date: Jun. 18, 2026

(54) INVERTER IN GALLIUM-NITRIDE TECHNOLOGY

(71) Applicant: IMEC VZW, Leuven (BE)

(72) Inventors: Katia Samperi, Bronte (IT); Urmimala Chatterjee, Wilsele (BE); Salvatore Pennisi, Catania (IT)

(21) Appl. No.: 19/414,144

(22) Filed: Dec. 9, 2025

(30) Foreign Application Priority Data
Dec. 17, 2024 (EP) 24220630.8

(51) Int. Cl. H03K 19/094; H03K 19/20

(52) U.S. Cl. CPC H03K 19/094; H03K 19/20

(57) ABSTRACT

A Gallium-Nitride inverter is provided using only n-type enhancement mode transistors to facilitate achieving Direct-Coupled-FET (DCFL) logic. The Gallium-Nitride inverter includes a first e-mode n-type GaN input transistor, which may be connected to a pull-up network. The pull-up network includes at least three e-mode n-type GaN transistors, such as a first e-mode n-type GaN transistor, a second e-mode n-type GaN transistor including a source and a drain, and a third e-mode n-type GaN transistor. The third e-mode n-type GaN transistor may be connected to the first drain of the e-mode n-type GaN input transistor.

### CROSS-REFERENCE TO RELATED APPLICATION(S)

The present application is a non-provisional patent application claiming priority to European Patent Application No. 24220630.8, filed Dec. 17, 2024, the contents of which are hereby incorporated by reference.

### BACKGROUND

Gallium Nitride has recently drawn attention as a wide bandgap material to replace narrow bandgap silicon-based CMOS technology. Integrated circuits manufactured in Gallium-Nitride technology may provide uses over silicon-based integrated circuits in the field of power electronics, radiofrequency power amplifiers and devices.

However, designing complementary logic Integrated Circuits (IC) in Gallium-Nitride (GaN) technology remains challenging. Current Gallium-Nitride technology provides (e.g., only) n-type enhancement (e-mode) and n-type depletion (d-mode) transistors, while exhibiting large process spreads, and lacking p-n junctions and complementary p-type enhancement (e-mode) devices.

A monolithically-integrated GaN integrated circuit (e.g., fully) utilizes the fast-switching capability of Gallium-Nitride technology by reducing the inductive parasitic and hence ringing at the gate of the transistor. This provides a fast and efficient switching operation and in turn a smooth and (e.g., highly) efficient circuit. However, there are challenges at the circuit level when realizing an integrated circuit in Gallium-Nitride technology. Due to the absence of a p-type enhancement GaN transistor, such integrated circuits may be designed using the n-type enhancement mode (e-mode) GaN transistors only. Therefore, it may be difficult to implement a Transistor-Transistor-Logic (TTL) in the design of such a circuit, e.g. an inverter circuit.

An inverter in Gallium-Nitride technology may be designed by a series connection of an enhancement mode (e-mode) n-type GaN FET and a resistor. For example, this series resistor may be a two-dimensional electron gas (2DEG) resistor. The pull-up mechanism of such an inverter is obtained by using a series resistor that connects the output of the inverter with a higher voltage line. Therefore, the basic building block in this technology becomes a Resistor-Transistor-Logic (RTL) inverter. The performance of such an inverter mainly depends on the optimization of the size of the series resistor, also referred to as load resistor. By increasing the size of this series resistor, it may be possible to increase the gain of the inverter and decrease the power dissipation. However, this comes at the penalty of longer time delays in the circuit. Hence, the trade-off between the switching speed and the power dissipation of such an inverter depends on the dimensioning of the series resistor.

An alternative for designing an inverter in Gallium-Nitride technology is to replace the 2DEG series resistor with an n-type depletion mode (d-mode) Gallium-Nitride transistor. This is called Direct-Coupled-FET (DCFL) logic. DCFL logic obtains higher speed over RTL logic with lower power dissipation. However, from a process technology viewpoint, an extra device type is used, i.e. the n-type d-mode logic transistor.

Thus, an inverter in Gallium-Nitride technology with a reduced set of device types and without a trade-off between switching speed and power dissipation would be useful.

### SUMMARY

A Gallium-Nitride inverter is provided. The Gallium-Nitride inverter (1) may include a first e-mode n-type GaN input transistor (2), whose gate (21) is a first input (Vᵢₙ₂) of the inverter (1), and whose drain (23) is connected to the output (Vₒᵤₜ₂) of the inverter (2), this drain (23) is connected to a pull-up network (3). The pull-up network (3) includes at least 3 e-mode n-type GaN transistors (4,5,6) whereby a first e-mode n-type GaN transistor (4) is configured as a diode by connecting its gate (41) to its drain (43), a second e-mode n-type GaN transistor (5) is configured as a capacitor by connecting its source (52) to its drain (53), and a third e-mode n-type GaN transistor (6), whose gate (61) is connected to the source (42) of the first e-mode n-type GaN transistor (4) and to the gate (51) of the second e-mode n-type GaN transistor (5), whose drain (63) is connected to the gate (41) of the first e-mode n-type GaN transistor (4), and whose source (62) is connected to the connected source (52) and drain (53) of the second e-mode n-type GaN transistor (5), and to the drain (23) of the e-mode n-type GaN input transistor (2).

The pull-up network (3) of this Gallium-Nitride inverter (1) may further include a resistor (7), inserted in between the first (2) and the third (6) e-mode n-type GaN transistor. One end (71) of the resistor (7) is connected to the source (62) of the third e-mode n-type GaN transistor (6), and the opposite end (72) of the resistor (7) is connected to the connected source (52) and drain (53) of the second e-mode n-type GaN transistor (5), and to the drain (23) of the e-mode n-type GaN input transistor (2).

Such an inverter may be used to form a logic gate, such as NOT, a NAND and a NOR logic gate. In a NAND logic gate, the inverter further includes a second e-mode n-type GaN input transistor (8), in series with the first e-mode n-type GaN input transistor (2); whose drain (83) is connected to the source (22) of the first e-mode n-type GaN transistor (2), and whose gate (81) is the second input (Vᵢₙ₃) to the inverter (1).

In a NOR logic gate, the inverter further includes a second e-mode n-type GaN input transistor (8), in parallel with the first e-mode n-type GaN input transistor (2), whose drain (83) is connected to drain (23) of the first e-mode n-type GaN input transistor (2), and whose gate (81) is the second input (Vᵢₙ₃) to the inverter (1).

Such an inverter and/or any logic gate including such an inverter may be used within an integrated circuit.

The e-mode n-type GaN transistor in the inverter and/or logic gate including such an inverter may be a HEMT.

### BRIEF DESCRIPTION OF THE FIGURES

The above, as well as additional, features will be better understood through the following illustrative and non-limiting detailed description of example embodiments, with reference to the appended drawings.

FIG. 1 is a conventional inverter.

FIG. 2 is an inverter according to an example embodiment.

FIGS. 3A, 3B, and 3C provide a comparison between an inverter according to a conventional inverter, such as the inverter of FIG. 1, and to an example embodiment.

FIG. 4 is a NAND logic gate according to an example embodiment.

FIG. 5 is a NOR logic gate according to an example embodiment.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the example embodiments set forth herein; rather, these embodiments are provided by way of example. Furthermore, like numbers refer to the same or similar elements or components throughout.

This disclosure addresses challenges when implementing Direct-Coupled-FET (DCFL) logic in Gallium-Nitride (GaN) technology without using an n-type depletion mode (d-mode) transistor. The (e.g., bootstrapped) Gallium-Nitride inverter according to this disclosure is useful when the Gallium-Nitride technology (e.g., only) provides an n-type enhancement mode (e-mode) Gallium-nitride transistor, such as High Electron Mobility Transistor (HEMT), which is often the case in Gallium-Nitride technology. The pull-up network of the (e.g., bootstrapped) inverter emulates an n-type depletion mode transistor behaviour which is a constant current source. Applying (e.g., only) n-type e-mode Gallium-Nitride transistors as the active components of the inverter and employing the bootstrapping principle, results in an inverter with improved performance compared to an inverter that uses a resistive pull-up network as is the case in Resistor-Transistor-Logic (RTL).

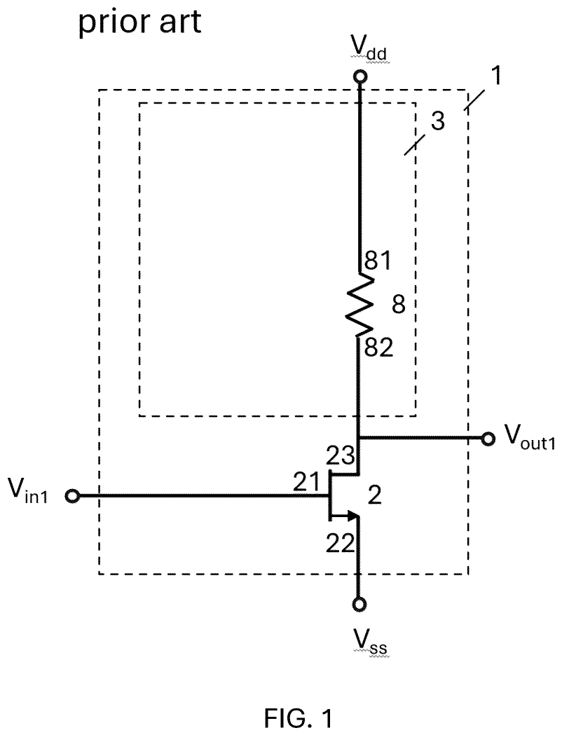

FIG. 1 is a (e.g., conventional) inverter (1) in Gallium-Nitride (GaN) technology, including a series connection of an enhancement mode (e-mode) n-type GaN transistor (2), such as a HEMT, also labelled as the pull-down network, and a resistor (8), also labelled as the pull-up network (3). The resistor (8) is connected at one end (82) (e.g., a first end) to the drain (23) of this transistor (2) and at the opposite end (81) (e.g., a second end) to a higher voltage line (V_{dd}). For example, this series resistor (8) is a two-dimensional electron gas (2DEG) resistor. The pull-up mechanism of the inverter (1) is achieved by the series resistor (8) connecting the output of the inverter (23,82) to the higher voltage line (V_{dd}). Therefore, the basic building block becomes a Resistor-Transistor-Logic (RTL) inverter.

The n-type e-mode input GaN transistor (2) receives a first input voltage signal (Vᵢₙ₁) at its gate (21). When the input voltage signal biases this gate (21) positively with respect to the source (22) of the transistor (2), current, provided via the resistor (8) from the higher voltage line (V_{dd}), can flow, from the drain (23) of the transistor (2) towards its source (22). The output voltage signal (Vₒᵤₜ₁) at the drain (23) of the transistor (2) is set to the voltage at source (22) of the transistor (2).

When the first input voltage signal (Vᵢₙ₁) biases this gate (21) equal to or negative with respect to the source (22) of the transistor (2), current, provided via the resistor (8) from the higher voltage line (V_{dd}), can no longer flow from the drain (23) of the transistor (2) towards its source (22). The output voltage signal (Vₒᵤₜ₁) at the drain (23) of the transistor (2) is then set to the voltage (V_{dd}) at the opposite end (81) of the resistor (8). The source (22) of the transistor (2) is connected to a lower voltage line (Vₛₛ).

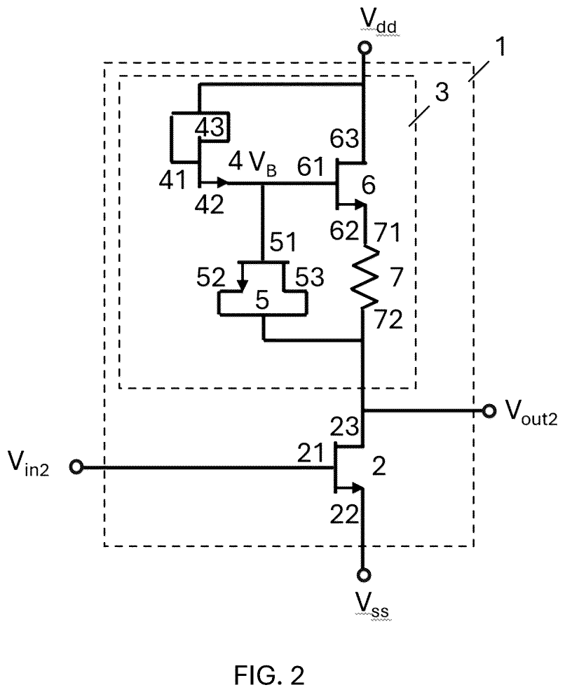

FIG. 2 is an inverter (1) according to an example embodiment. The inverter comprises a pull-down network, including the first input transistor (2), and a pull-up network (3). The pull-up network (3) of this inverter (1) includes at least three n-type e-mode GaN transistors. For example, HEMT's may include a first transistor (4), a second transistor (5) and a third transistor (6) and, optionally, a resistor (7). This resistor is compatible with Gallium-Nitride technology in which the GaN transistors (2,4,5,6) are manufactured.

In the pull-up network (3), the first transistor (4) behaves as a diode as its drain (43) and its gate (41) are connected. Second transistor (5) behaves as a capacitance as its drain (52) and its source (53) are connected. Third transistor (6) provides a current path between the output of the inverter, being the drain (23) of the first input transistor (2), and a higher voltage line (V_{dd}) at the drain (63) of the third transistor (6). The drain (43) of the first transistor (4) is connected to the drain (63) of the third transistor (6), while its source (42) is connected to both the gate (61) of the third transistor (6) and to the gate (51) of the second transistor (5). The drain (53) of this second transistor (5) is connected to the drain (23) of the first input transistor (2). The source (22) of the first input transistor (2) is connected to a lower voltage line (Vₛₛ).

In an example embodiment, an optional resistor (7) is present. This resistor (7) may then be inserted between the output of the inverter (1), i.e., the drain (23) of the first input transistor (2), and the source (62) of the third transistor (6). When present, this resistor (7) reduces the current conveyed by the third transistor (6).

When the first input voltage signal (Vᵢₙ₂) at the gate (21) of the first input transistor (2) is high, compared to the voltage at its source (22), the output voltage signal (Vₒᵤₜ₂) at the drain (23) of this transistor (2) is set to the voltage of the source (22) of this transistor (2). Transistor (2) then charges the capacitance-connected second transistor (5) through the diode-connected first transistor (4). The voltage (V_{B}), at the gate (61) of the third transistor (6), increases to the level of the voltage across the capacitance-connected second transistor (5). This voltage level may be the voltage (V_{dd}) at the drain (63) of the third transistor (6) minus the threshold voltage (V_{th_4}) of the diode-connected first transistor (4), as shown in the following equation of V_{dd}−V_{th_4}. Due to this voltage increase, the third transistor (6) is turned-on, providing current to the drain (23) of the first input transistor (2).

When the first input voltage signal (Vᵢₙ₂) at the gate (21) of the first input transistor (2) is low or negative, compared to the voltage at its source (22), the output voltage signal (Vₒᵤₜ₂) at the drain (23) of this transistor (2) is set to the voltage of the drain (63) of the third transistor (6). The capacitance-connected second transistor (5) cannot discharge now via the first input transistor (2). The voltage (V_{B}), at the gate (61) of the third transistor (6), follows the increase of the output voltage signal (Vₒᵤₜ₂) at the drain (23) of the first input transistor (2). Finally, this voltage (V_{B}) reaches a voltage level of two times the voltage (V_{dd}) at the drain (63) of the third transistor (6) minus the threshold voltage (V_{th_4}) of the diode-connected first transistor (4), as shown by the following equation of 2*V_{dd}−V_{th_4}. As the diode-connected first transistor (4) is now switched off, the voltage at the gate (61) of the third transistor (6) is kept (e.g., substantially) constant. The third transistor (6) now acts like an n-type depletion-mode (d-mode) transistor.

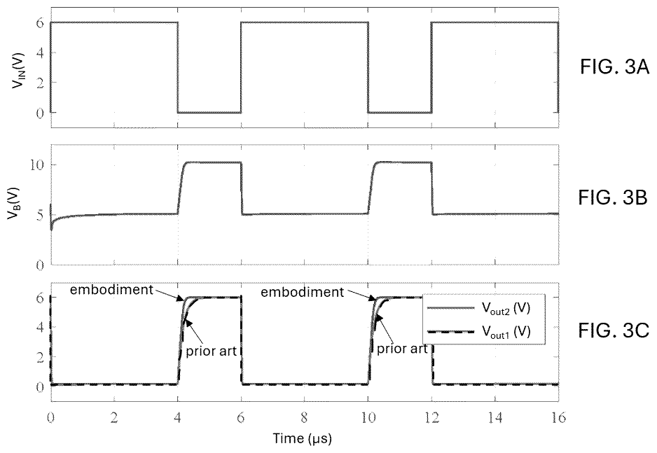

FIGS. 3A, 3B, and 3C provide the voltage variation for a conventional inverter, as illustrated by FIG. 1, and an inverter according to this example embodiment, as illustrated by FIG. 2. A supply voltage (V_{dd}) of 6 V at the drain (63) of the third transistor (6) is assumed.

FIG. 3A is the variation of the first input voltage signal (Vᵢₙ₁) over time.

FIG. 3B is the corresponding variation over time of the voltage (V_{B}) at the gate (61) of the third transistor (6), when the first input voltage signal (Vᵢₙ₁) is low and when the input voltage (Vᵢₙ₁) is high.

FIG. 3C compares the corresponding variation over time of the output voltage signal (Vₒᵤₜ₂) of the inverter according to this example embodiment, illustrated by FIG. 2, and of the output voltage signal (Vₒᵤₜ₁) of a conventional inverter, illustrated by FIG. 1. The main difference between both output voltage signals lies in the rise time. The inverter according to this example embodiment is faster than the conventional inverter. When the transistor (1) in the pull-down network is off, the current coming from the pull-up network (3) charges the capacitance at the output of the inverter (1) (not shown). For the conventional inverter, the current flowing through resistor (8) decreases as its output voltage (Vₒᵤₜ₁) increases, as provided by Ohm's law, thereby slowing down the low-to-high transition of this output voltage (Vₒᵤₜ₂). For the inverter according to this example embodiment, its pull-up network (1) generates a constant current attributable to the bootstrapping principle that biases the third transistor (6) with a constant gate (61)-to-source (62) voltage. Hence the output voltage (Vₒᵤₜ₂) of the inverter according to this example embodiment shows a faster low-to-high transition.

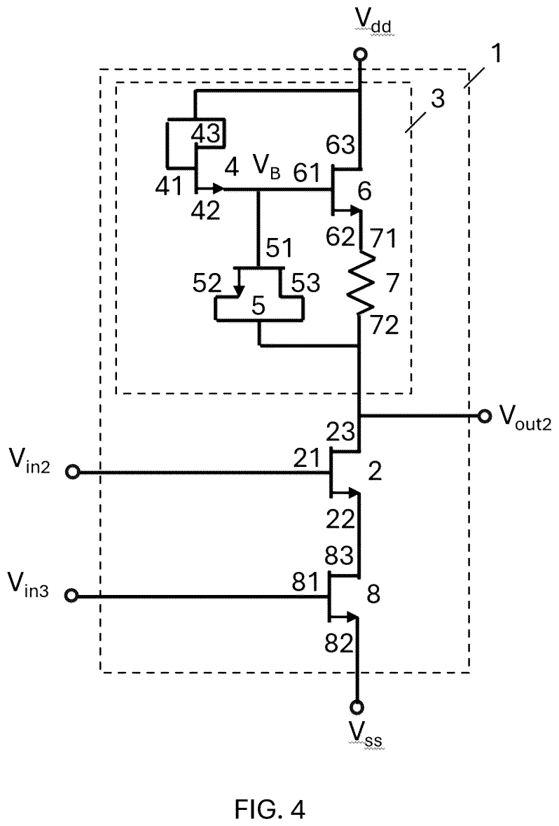

FIG. 4 shows a NAND logic gate according to an example embodiment. Whereas the inverter circuit shown in FIG. 2, only has a first n-type e-mode GaN input transistor (2) receiving the first input voltage signal (Vᵢₙ₂) at its gate (21), this NAND logic gate (1) has a second n-type e-mode GaN input transistor (8), such as a HEMT. This second input transistor (8) is connected in series between the first input transistor (2) and the lower voltage line (Vₛₛ). The drain (83) of this second input transistor (8) is connected to the source (22) of the first input transistor (2), while the source (82) of this second input transistor (8) is connected to the lower voltage line (Vₛₛ). This second input transistor (8) receives a second input voltage signal (Vᵢₙ₃) at its gate (81).

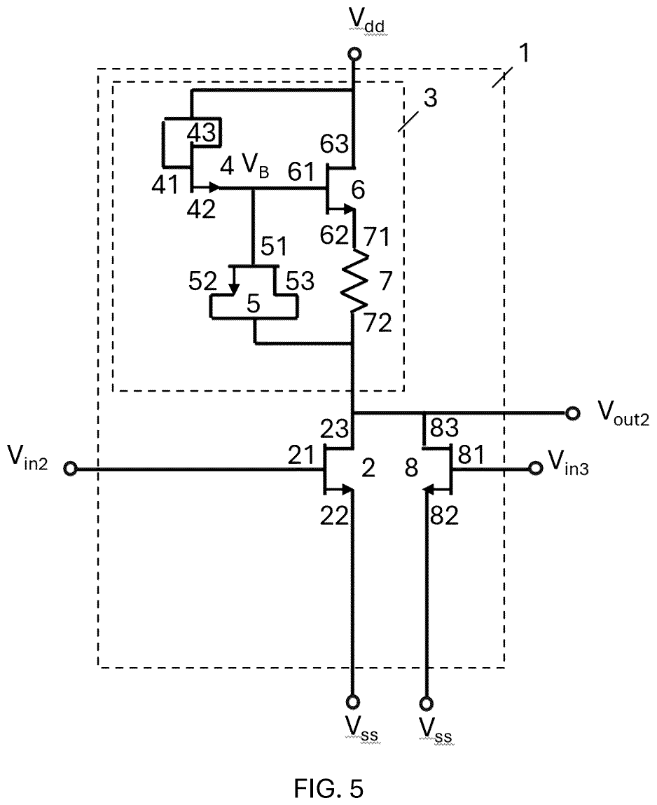

FIG. 5 shows a NOR logic gate according to an example embodiment. The inverter circuit shown in FIG. 2 has (e.g., only) a first n-type e-mode GaN input transistor (2) receiving the first input voltage signal (Vᵢₙ₂) at its gate (21), this NAND logic gate (1) has a second n-type e-mode GaN input transistor (8), such as a HEMT. This second input transistor (8) is connected in parallel to the first input transistor (2). The drain (83) of this second input transistor (8) is connected to the drain (23) of the first input transistor (2), while the source (82) of this second input transistor (8) is connected to the lower voltage line (Vₛₛ). This second input transistor (8) receives a second input voltage signal (Vᵢₙ₃) at its gate (81).

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A Gallium-Nitride inverter comprising:
a first e-mode n-type GaN input transistor, wherein the first e-mode n-type GaN input transistor includes:
a first gate, wherein the first gate is an input of the inverter; and
a first drain, wherein the first drain is connected to an output of the inverter and connected to a pull-up network, wherein the pull-up network includes at least three e-mode n-type GaN transistors, the at least three e-mode n-type GaN transistors of the pull-up network include:
a first e-mode n-type GaN transistor including a gate and a drain, wherein the first e-mode n-type GaN transistor is configured as a diode by connecting the first e-mode n-type GaN transistor gate to the first e-mode n-type GaN transistor drain,
a second e-mode n-type GaN transistor including a source and a drain, wherein the second e-mode n-type GaN transistor is configured as a capacitor by connecting the second e-mode n-type GaN transistor source to the second e-mode n-type GaN transistor drain, and
a third e-mode n-type GaN transistor including a gate, a source, and a drain, wherein
the third e-mode n-type GaN transistor gate is connected to a source of the first e-mode n-type GaN transistor and to a gate of the second e-mode n-type GaN transistor, the third e-mode n-type GaN transistor drain is connected to the first e-mode n-type GaN transistor gate, and the third e-mode n-type GaN transistor source is connected to the second e-mode n-type GaN transistor source and the second e-mode n-type GaN transistor drain, and to the first drain of the first e-mode n-type GaN input transistor.

2. The inverter of claim 1, wherein the pull-up network further comprises a resistor.

3. The inverter of claim 2, wherein the resistor is inserted between the first and the third e-mode n-type GaN transistor.

4. The inverter of claim 2, wherein a first end of the resistor is connected to the third e-mode n-type GaN transistor source.

5. The inverter of claim 4, wherein a second end of the resistor is connected to the second e-mode n-type GaN transistor source and the second e-mode n-type GaN transistor drain.

6. The inverter of claim 5, wherein the second end of the resistor is also connected to the first drain of the first e-mode n-type GaN input transistor.

7. A logic gate comprising an inverter, the inverter is a Gallium-Nitride inverter, wherein the inverter comprises:
a first e-mode n-type GaN input transistor, wherein the first e-mode n-type GaN input transistor includes:
a first gate, wherein the first gate is an input of the inverter; and
a first drain, wherein the first drain is connected to an output of the inverter and connected to a pull-up network, wherein the pull-up network includes at least three e-mode n-type GaN transistors, the at least three e-mode n-type GaN transistors of the pull-up network include:
a first e-mode n-type GaN transistor including a gate and a drain, wherein the first e-mode n-type GaN transistor is configured as a diode by connecting the first e-mode n-type GaN transistor gate to the first e-mode n-type GaN transistor drain,
a second e-mode n-type GaN transistor including a source and a drain, wherein the second e-mode n-type GaN transistor is configured as a capacitor by connecting the second e-mode n-type GaN transistor source to the second e-mode n-type GaN transistor drain, and
a third e-mode n-type GaN transistor including a gate, a source, and a drain, wherein the third e-mode n-type GaN transistor gate is connected to a source of the first e-mode n-type GaN transistor and to a gate of the second e-mode n-type GaN transistor,
the third e-mode n-type GaN transistor drain is connected to the first e-mode n-type GaN transistor gate, and the third e-mode n-type GaN transistor source is connected to the second e-mode n-type GaN transistor source and the second e-mode n-type GaN transistor drain, and to the first drain of the first e-mode n-type GaN input transistor.

8. The logic gate of claim 7, wherein the pull-up network further comprises a resistor.

9. The logic gate of claim 8, wherein the resistor is inserted in between the first and the third e-mode n-type GaN transistor.

10. The logic gate of claim 8, wherein a first end of the resistor is connected to the third e-mode n-type GaN transistor source.

11. The logic gate of claim 10, wherein a second end of the resistor is connected to the second e-mode n-type GaN transistor source and the second e-mode n-type GaN transistor drain.

12. The logic gate of claim 11, wherein the second end of the resistor is also connected to the first drain of the first e-mode n-type GaN input transistor.

13. The logic gate of claim 7 is a NOT gate.

14. The logic gate of claim 7 is a NAND gate.

15. The logic gate of claim 9, further comprising:
a second e-mode n-type GaN input transistor is in series with the first e-mode n-type GaN input transistor, wherein the second e-mode n-type GaN input transistor includes:
a drain connected to the first e-mode n-type GaN transistor source, and
a gate, wherein the gate is a second input to the inverter.

16. The logic gate of claim 7, wherein the logic gate is a NOR gate.

17. The logic gate of claim 11, further comprising:
a second e-mode n-type GaN input transistor is in parallel with the first e-mode n-type GaN input transistor, wherein the second input e-mode n-type GaN transistor includes:
a drain connected to the first drain of the first e-mode n-type GaN input transistor, and
a gate, wherein the gate is a second input to the inverter.

18. A device according to the claim 1, wherein at least one of the first e-mode n-type GaN transistor, the second e-mode n-type GaN transistor, or the third e-mode n-type GaN transistor is a HEMT.

19. An integrated circuit comprising the Gallium-Nitride inverter of claim 1.

20. The integrated circuit of claim 19, wherein the pull-up network further comprises a resistor.
